(19) United States
(12) Patent Application Publication
(10) Pub. No.: US 2012/0032306 A1
(43) Pub. Date: Feb. 9, 2012

(54) Method for Patterning a Semiconductor Surface, and Semiconductor Chip

(75) Inventors: Elmar Baur, Regensburg (DE); Bernd Böhm, Regensburg (DE); Alexander Heindl, Abensberg (DE); Patrick Rode, Regensburg (DE); Matthias Sabathil, Regensburg (DE)

(73) Assignee: OSRAM Opto Semiconductors GmbH, Regensburg (DE)

(21) Appl. No.: 13/148,631

(22) PCT Filed: Jan. 22, 2010
(86) PCT No.: PCT/EP10/50742

§ 371 Date: Oct. 24, 2011

(30) Foreign Application Priority Data
Feb. 10, 2009 (DE) 10 2009 008 223.9

(51) Int. Cl. H01L 29/12; H01L 21/312

(52) U.S. Cl. 257/613; 438/694; 257/E21.259; 257/E29.068

(57) ABSTRACT

A method for patterning a semiconductor surface is specified. A photoresist is applied to an outer area of a second semiconductor wafer. A surface of the photoresist that is remote from the second semiconductor wafer is patterned by impressing a patterned surface of the first wafer into the photoresist. A patterning method is applied to the surface of the photoresist, wherein a structure applied on the photoresist is transferred at least in places to the outer area of the second semiconductor wafer.

This patent application is a national phase filing under section 371 of PCT/EP2010/050742, filed Jan. 22, 2010, which claims the priority of German patent application 10 2009 008 223.9, filed Feb. 10, 2009, each of which is incorporated herein by reference in its entirety.

### TECHNICAL FIELD

A method for patterning a semiconductor surface, and a semiconductor chip are specified.

### BACKGROUND

The German patent document DE 103 067 79 A1 describes a method for roughening a surface of a body and optoelectronic component.

### SUMMARY OF THE INVENTION

In one aspect, the present invention provides a method for patterning a semiconductor surface which is time-saving and furthermore cost-effective.

In accordance with at least one embodiment of the method, a first wafer is provided, which has a patterned surface. Furthermore, a second semiconductor wafer is provided. The first wafer and the second semiconductor wafer can be embodied in the manner of discs or plates.

The first wafer has a patterned surface. In this context, “patterned” means that elevations and depressions are situated at least in places on the surface, for example, at the top side on a top area of the first wafer. The patterned surface can be formed, for example, with prefabricated, regular structures that are introduced into the top area in a controlled manner. The structures can be embodied in relief- or trench-like fashion.

In accordance with at least one embodiment of the method in a next step, a photoresist is applied to the outer areas of the second semiconductor wafer. Preferably, the photoresist has a thickness of 1 to 10 μm.

In accordance with at least one embodiment of the method, the surface of the photoresist that is remote from the second semiconductor wafer is patterned by impressing the patterned surface of the first wafer into the photoresist.

If the patterned surface of the first wafer faces the surface of the photoresist that is remote from the second semiconductor wafer, then the first wafer and the second semiconductor wafer can be brought together and, for example, pressed together in such a way that the patterned surface of the first semiconductor wafer is impressed at least in places into the surface of the photoresist. In this respect, “impressing” means that at places at which elevations are situated on the surface of the first wafer, corresponding depressions are mapped on the surface of the photoresist. The same happens with depressions situated on the surface of the first wafer, which are mapped as elevations into the surface of the photoresist. It is likewise possible for the patterned surface of the first wafer to be completely impressed into the surface of the photoresist.

The photoresist is a soft material which can deform while the two semiconductor wafers are being pressed together. After the removal of the second semiconductor wafer from the photoresist, the patterned surface of the photoresist then retains its surface structure. In other words, the impressing operation is a process in which the surface of the photoresist is permanently patterned.

In accordance with at least one embodiment of the method, a patterning method is applied to the patterned surface of the photoresist, wherein the structure applied to the photoresist is transferred at least in places to the outer area of the second semiconductor wafer. The outer area is the surface of the second semiconductor wafer that faces the photoresist and which is covered by the photoresist. That is to say that the structure situated on the photoresist is transferred to the outer area of the second semiconductor wafer at least in places using the patterning method.

In accordance with at least one embodiment of the method, a first wafer is provided, which has a patterned surface. Onto a second semiconductor wafer provided, a photoresist is applied to the outer areas of the second semiconductor wafer. In a next step, that surface of the photoresist that is remote from the second semiconductor wafer is patterned by impressing the patterned surface of the first wafer into the photoresist. A patterning method is subsequently applied to the patterned surface of the photoresist, wherein the structure applied to the photoresist is transferred at least in places to the outer area of the second semiconductor wafer.

In this case, the method for patterning a semiconductor surface as described here is based, inter alia, on the insight that the patterning of a semiconductor surface can be associated with elaborate effort and is at the same time cost-intensive.

In order, then, to arrive at a time-saving and cost-effective method for patterning a semiconductor surface, the method described here makes use of the concept of firstly providing a first wafer, which has a patterned surface. In the method that follows, the patterned surface of the first wafer serves as a template within the production process. The aim of the method, then, is to apply patterned surfaces on semiconductor wafers of different materials. For this purpose, by way of example, a second semiconductor wafer is provided, on which a photoresist is applied. After impressing the patterned surface of the first wafer into the photoresist, it is possible, after applying a patterning method, for the patterned surface of the photoresist to be transferred at least in places into the outer area of the second semiconductor wafer. By virtue of the fact that the patterned surface of the first wafer can be repeatedly used as a template, the operation can be repeated and it is thus possible to produce a multiplicity of further semiconductor wafers with an applied structure on their respective outer areas. The reuse of the first wafer as a template for applying the structure to the outer area of the second semiconductor wafer therefore not only leads to a cost saving in the production method, but likewise enables fast and time-saving production.

In accordance with at least one embodiment of the method, the first wafer is a semiconductor wafer. First and second semiconductor wafers are then each formed with at least one semiconductor material. In this case, first and second semiconductor wafers are formed from mutually different materials.

Furthermore, one or a plurality of layers composed of a semiconductor material can be epitaxially deposited at least in places both on the first and on the second semiconductor wafer. Both the first and the second semiconductor wafer can comprise active regions for emitting electromagnetic radiation. By way of example, first and/or second semiconductor wafer can comprise a multiplicity of semiconductor chips which are present in an assemblage.

In accordance with at least one embodiment of the method, the first wafer is an intermediate carrier formed from a plastics material. The intermediate carrier can be embodied in the manner of plates or discs. In order to produce a patterned surface of the intermediate carrier, by way of example, a semiconductor wafer having a patterned surface is provided. That surface of the intermediate carrier which faces the semiconductor wafer is then patterned by impressing the patterned surface of the semiconductor wafer into the intermediate carrier.

If the patterned surface of the semiconductor wafer faces the surface of the intermediate carrier, then the semiconductor wafer and the intermediate carrier can be brought together and, for example, pressed together in such a way that the patterned surface of the semiconductor wafer is impressed into the surface of the intermediate carrier at least in places. It is likewise possible for the patterned surface of the semiconductor wafer to be completely impressed into the surface of the intermediate carrier. After the removal of the semiconductor wafer from the intermediate carrier, the patterned surface of the intermediate carrier then retains its surface structure. In other words, the impressing operation is a process in which the surface of the intermediate carrier is permanently patterned.

In the patterning method, the intermediate carrier can, then, serve as a template-like original and thus replace some other first wafer, for example, a cost-intensive semiconductor wafer. The intermediate carrier can be reused many times. Preferably, the intermediate carrier is formed with a “readily patternable” material. In this context, “readily patternable” means that the intermediate carrier is preferably formed with a plastic-like and/or readily impressible material. This advantageously enables cost-effective mass production.

In accordance with at least one embodiment of the method, the maximum diameter of the first wafer deviates by at most 20%, preferably by at most 10%, especially preferably by at most 5%, from the maximum diameter of the second semiconductor wafer. That is to say that the two wafers have laterally approximately the same dimensions or same dimension. In this context, “laterally” means the dimension with respect to the maximum diameter of the two semiconductor wafers.

By way of example, the top areas of the first wafer and of the second semiconductor wafer can be embodied in oval or circular fashion. It is advantageously ensured that the first wafer and the second semiconductor wafer are as far as possible congruent upon being brought together, thus minimizing regions both on the first wafer and on the second semiconductor wafer which are not associated with or do not contribute to the patterning process.

In accordance with at least one embodiment of the method, the first wafer comprises at least one layer which consists of a nitride-based compound semiconductor material. In the present context, “nitride-based compound semiconductor material” means that the first wafer and/or the active layer contained in the first wafer, for example, comprises or consists of a nitride compound semiconductor material, preferably AlₙGaₘIn₁₋ₙ₋ₘN, where 0≦m≦1, 0≦n≦1 and m+n≦1. In this case, this material need not necessarily have a mathematically exact composition according to the above formula. Rather, it can comprise, for example, one or more dopants and additional constituents. For the sake of simplicity however, the above formula only includes the essential constituents of the crystal lattice (Al, Ga, In, N), even if these can be replaced and/or supplemented in part by small amounts of further substances. By way of example, the compound semiconductor material is aluminum gallium indium nitride (AlGaInN). This semiconductor material is suitable, in particular, for light-emitting diodes which emit electromagnetic radiation in the ultraviolet to blue spectral range.

In accordance with at least one embodiment of the method, the second semiconductor wafer comprises at least one layer which consists of a phosphide-based compound semiconductor material. In an equivalent manner, “phosphide-based compound semiconductor material” means that the second semiconductor wafer and/or the active layer contained in the second semiconductor wafer, for example, preferably comprises AlₙGaₘIn₁₋ₙ₋ₘP, where 0≦m≦1, 0≦n≦1 and m+n≦1. In this case, this material, too, need not necessarily have a mathematically exact composition according to the above formula. Rather, it can comprise one or more dopants and additional constituents. For the sake of simplicity, however, the above formula only includes the essential constituents of the crystal lattice (Al, Ga, In, P), even if these can be replaced in part by small amounts of further substances. If the second semiconductor wafer comprises the compound semiconductor material aluminum gallium indium phosphide (AlGaInP), then this compound semiconductor material is advantageously used for light-emitting diodes which emit in the yellow to red spectral range.

In accordance with at least one embodiment of the method, the second semiconductor wafer comprises at least one layer which consists of an arsenide-based compound semiconductor material. Likewise in an equivalent manner, “arsenide-based compound semiconductor material” means that the second semiconductor wafer and/or the active layer contained in the second semiconductor wafer, for example, preferably comprises AlₙGaₘIn₁₋ₙ₋ₘAs, where 0≦m≦1, 0≦n≦1 and m+n≦1. This material, too, need not necessarily have a mathematically exact composition according to the above formula and can comprise one or more dopants and additional constituents which essentially do not change the characteristic physical properties of the AlₙGaₘIn₁₋ₙ₋ₘAs-material. For the sake of simplicity, however, the above formula only includes the essential constituents of the crystal lattice (Al, Ga, In, As), even if these can be replaced in part by small amounts of further substances. If the second semiconductor wafer comprises the compound semiconductor material aluminum gallium arsenide (AlGaAs), then this compound semiconductor material is suitable particularly for generating infrared radiation.

Compound semiconductor materials such as phosphide compound semiconductors and arsenide compound semiconductors are particularly suitable for the formation of a semiconductor layer sequence for efficient semiconductor chips, in particular of active regions/layers having a height quantum efficiency.

In accordance with at least one embodiment of the method, the patterning method is a dry-chemical etching process. Consideration is given, for example, to methods such as reactive ion etching (RIE), ion beam etching (IBE) and chemically assisted ion beam etching (CAIBE) and so on. By way of example, consideration is also given to using, as a dry etching method, a method using a high-density plasma such as, for example, an inductively coupled plasma etching method (ICP=Inductively Coupled Plasma), ECR plasma (ECR=Electron Cyclotron Resonance) or a helicon plasma. In the case of the present method, dry etching methods have the advantage of having a preferred direction during etching (anisotropy). On account of the anisotropy, it is possible to produce good aspect ratios, that is to say very steep structures in the body to be etched.

In accordance with at least one embodiment of the method, the patterning method is a wet-chemical etching process. In this context, “wet-chemical” means that etching liquids are applied to the patterned surface of the photoresist and the photoresist is etched away by means of a chemical reaction. If the etching liquid reaches the outer area of the second semiconductor wafer, then etched-in structures also arise in the second semiconductor wafer, which structures can be set and configured depending on the choice of the etching liquid and depending on the concentration of the etching constituents in the etching liquid.

In accordance with at least one embodiment of the method, the structure mapped onto the outer area of the second semiconductor wafer is embodied in pyramid-like fashion. That is to say that the outer area of the second semiconductor wafer has a structure which can be formed by a multiplicity of pyramid-like elevations. Each pyramid-like elevation is a polyhedron and is delimited by a lateral area, a base area and a top area. The lateral area has at least three side areas which converge and laterally delimit the top area. The base area is laterally delimited by the side areas of the pyramid-like elevation. The side areas of the pyramid-like elevation end in the second semiconductor wafer and form the base area there. Base area and top area of the pyramid-like elevation are therefore situated opposite one another and are connected to one another via the side areas. In a lateral section through such a pyramid-like elevation, the pyramid-like elevation has at least two side areas, a top area and a base area. Preferably, top area and base area are embodied in hexagonal fashion. Preferably, the ratio of the area content of top area to base area is 1/5 or less.

In order to produce roughening structures in semiconductor wafers, a dry-chemical roughening process has been employed hitherto, in particular, with regard to phosphide- and arsenide-based compound semiconductor materials. In this case, trapezium-like roughening structures can arise. In this context, “trapezium-like” means that, by way of example, in a lateral section through such a roughening structure, the roughening structure has a multiplicity of trapezium-like elevations. Each trapezium-like elevation is formed by at least two side areas, a top area and a base area, wherein the area size ratio of top area to base area is at least four times the area size ratio of top area to base area of a pyramid-like elevation.

For nitride-based compound semiconductor materials, it is possible to employ an anisotropic chemical etching method, for example, a dry-chemical etching process, which leads to pyramid-like structures.

It has not been possible to achieve the pyramid-like structures hitherto in the case of phosphide- and arsenide-based compound semiconductor materials.

It can be shown that a radiation coupling-out area of a semiconductor chip that is embodied in pyramid-like fashion has an increased coupling-out efficiency in comparison with a structure of the radiation coupling-out area that is embodied in trapezium-like fashion. The radiation coupling-out area of a semiconductor chip forms the surface through which the electromagnetic radiation generated by the semiconductor chip is coupled out. “Coupling-out efficiency” is the ratio of luminous energy actually coupled out from the semiconductor chip to the luminous energy generated primarily within the semiconductor chip.

The method claimed here advantageously affords the possibility of also forming pyramid-like structures in surfaces of phosphide- and arsenide-based compound semiconductor materials.

In accordance with at least one embodiment of the method, a ratio of etching depth t to width b holds true for the pyramid-like structure, the relationship being 0.1<t/b<10. The etching depth t is, for example, the distance along a normal to the surface of the second semiconductor wafer from the top area of the pyramid-like elevation as far as the base area thereof. The etching depth t therefore simultaneously corresponds to the height of the pyramid-like elevation. If a pyramid-like elevation is considered in a side view, then, for example, the width b is defined as the edge length of the base area of a pyramid-like elevation.

The ratio t/b is preferably chosen as follows: 0.25<t/b<5, especially preferably 0.5<t/b<2.

Such a depth-to-width ratio is particularly advantageous in order to improve the scattering at a radiation coupling-out area embodied in pyramid-like fashion, for example, a radiation coupling-out area of a semiconductor chip. The etching-depth-to-width ratio mentioned can be individually set by means of a suitable choice of the etching process and also, for example, by means of the constitution and thickness of the photoresist.

A selectivity of the etching process, with respect to the materials of the photoresist and of the second semiconductor wafer, is preferably set at 1:1, such that the surface patterning of the photoresist is transferred into the outer area of the second semiconductor wafer.

In accordance with at least one embodiment of the method the etching depth t in the second semiconductor wafer is 50 nm to 2 μm. It can be shown that such an etching depth of the pyramid-like structures further intensifies the effects mentioned. The etching depth t can be achieved, for example, by using an etching process having a suitable selectivity between the photoresist and the second semiconductor wafer. The selectivity is preferably a value of 1:1. Furthermore, the etching duration also has to be chosen in a suitable manner in order to achieve the desired etching depth. Preferably, in the case of the method described here, the photoresist layer is applied with a thickness of between 1 and 10 μm. A specific maximum thickness of the photoresist should not be exceeded, in order that the time duration required for etching through the photoresist layer is kept within limits.

Furthermore, a semiconductor chip is also specified, comprising a semiconductor body based on phosphide- or arsenide-based compound semiconductor materials.

The semiconductor body has an epitaxially grown semiconductor layer sequence having at least one zone which is active for generating electromagnetic radiation.

In accordance with at least one embodiment of the semiconductor chip, the electromagnetic radiation generated in the semiconductor body is coupled out from the semiconductor chip through a radiation exit area, wherein the radiation exit area is patterned in pyramid-like fashion. The radiation exit area of the semiconductor chip runs, for example, parallel to the expitaxially grown semiconductor layer sequence of the semiconductor body. In this case, the radiation exit area is that surface of the semiconductor chip which is remote from the semiconductor body and through which the electromagnetic radiation generated by the semiconductor body emerges. Furthermore, the radiation exit area is patterned in pyramidal fashion. That is to say that the radiation exit area has a multiplicity of elevations embodied in pyramid-like fashion. It can be shown that such pyramid-like elevations of the radiation exit area of a semiconductor chip increase the coupling-out efficiency of the electromagnetic radiation from a semiconductor chip in comparison with, for example, trapezium-like structures.

In accordance with at least one embodiment of the semiconductor chip, such a semiconductor chip can be produced by the method claimed here. That is to say that the features described in conjunction with the method are also disclosed in conjunction with the semiconductor chip.

### BRIEF DESCRIPTION OF THE DRAWINGS

The method described here and also a semiconductor chip are explained in greater detail below on the basis of exemplary embodiments and the associated figures.

FIG. 1A shows in a schematical sectional illustration, a semiconductor wafer with an outer area embodied in trapezium-like fashion;

FIG. 1B shows in a schematical sectional illustration, a semiconductor wafer with an outer area embodied in pyramid-like fashion;

FIGS. 2 and 3 show individual fabrication steps for producing an exemplary embodiment by means of a method described here;

FIG. 4 shows, in a schematic sectional illustration, an assemblage composed of a multiplicity of semiconductor chips; and

FIG. 5 shows individual method steps for patterning an intermediate carrier.

In the exemplary embodiment and the figures, identical or identically acting constituent parts are in each case provided with the same reference symbols. The elements illustrated should not be regarded as true to scale, rather, individual elements may be illustrated with an exaggerated size in order to afford a better understanding.

### DETAILED DESCRIPTION OF ILLUSTRATIVE EMBODIMENTS

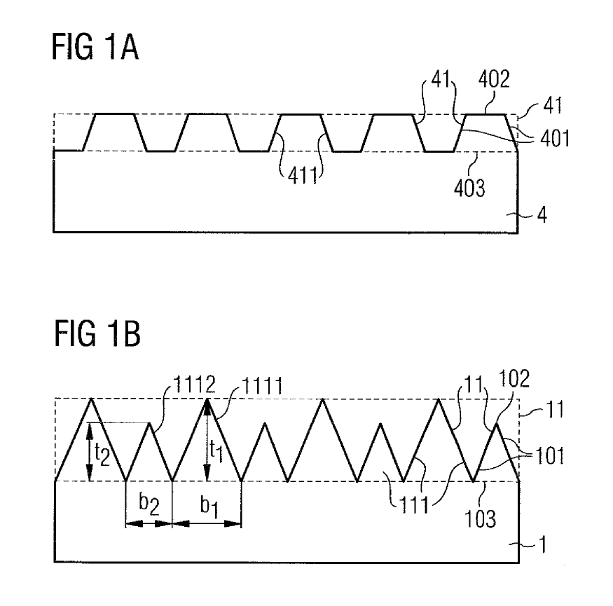

FIG. 1A shows, on the basis of a schematic sectional illustration, a semiconductor wafer 4 having a surface 41 patterned in trapezium-like fashion. In the present case, the semiconductor wafer 4 consists of phosphide- and/or arsenide-based compound semiconductor materials. The surface 41 is formed by a plurality of trapezium-like elevations 411. Each trapezium-like elevation 411 is formed by in each case two side areas 401, a top area 402 and a base area 403. The area ratio of the top area 402 to the base area 403 is 4:5, for example.

The wafer 1 shown in FIG. 1B is a semiconductor wafer and is based on a nitride-based compound semiconductor material. A surface 11 of the wafer 1 has a pyramid-like structure. That is to say that the surface 11 of the wafer 1 is formed from a plurality of pyramid-like elevations 111. In the present exemplary embodiment, along the surface 11 of the wafer 1, a pyramid-like elevation 1111 having the depth t₁ and the width b₁ respectively alternates with a pyramid-like elevation 1112 having the depth t₂ and width b₂, such that the surface 11 is formed with periodically recurring pyramid-like elevations 1111 and 1112. Each pyramid-like elevation 1111 and 1112 has a depth-to-width ratio of t/b=2. Preferably, the etching depth of the pyramid-like structures 111 is 50 nm to 2000 nm, preferably 75 nm to 1500 nm, in the present case 100 nm to 1000 nm.

In a lateral sectional illustration of a pyramid-like elevation 111, each pyramid-like elevation 111 is formed by in each case two side areas 101, a top area 102 and a base area 103. In FIG. 1B, the top area has such small dimensions that it is illustrated as a point in the form of a tip in FIG. 1B. The area ratio of the top area 102 to the base 103 is 1:5. In the present case, the area ratio of top area to base area of a trapezium-like elevation is greater by a factor of four than that of a pyramid-like elevation.

It can be shown that such pyramid-like elevations 111, which, for example, form a radiation exit area of a semiconductor chip, increase the coupling-out efficiency in particular in comparison with the trapezium-shaped structures 411 shown in FIG. 1A.

However, hitherto it has been possible for such surfaces embodied in pyramid-like fashion to be produced only in the case of nitride-based compound semiconductor materials.

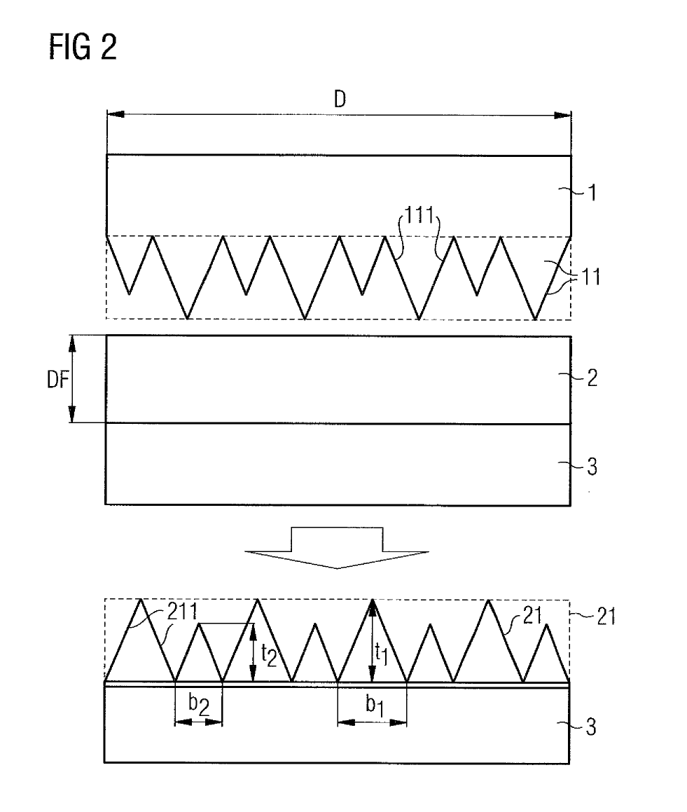

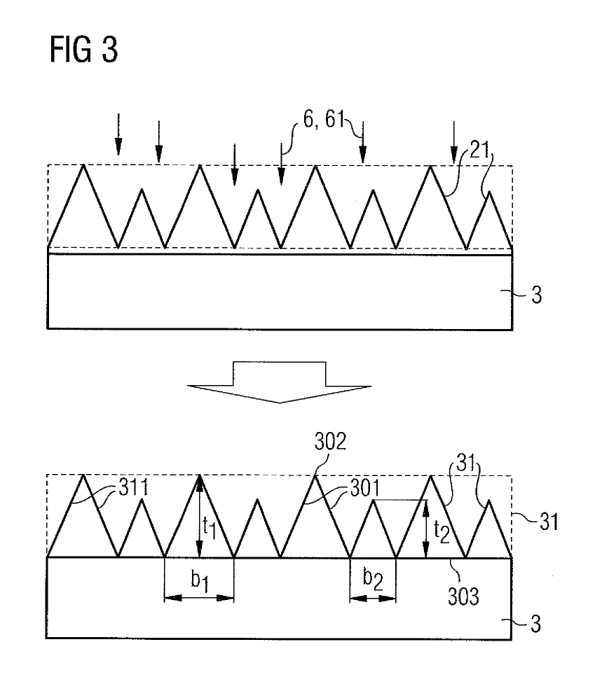

FIGS. 2 and 3 show individual fabrication steps for producing an outer area 31, [[-]] patterned in pyramid-like fashion, of a semiconductor wafer 3 consisting of phosphide- and/or arsenide-based compound semiconductor materials.

Firstly, the wafer 1 is provided. A photoresist layer 2 is applied to the semiconductor wafer 3. The photoresist layer 2 has a thickness DF of 1 μm. Both the wafer 1 and the semiconductor wafer 3 are embodied in the manner of discs which, in a plan view, in each case form a circular area and in this case have a diameter D.

In a next method step, the surface 11 of the wafer 1 that is embodied in pyramid-like fashion is pressed on, for example, into the photoresist 2 in such a way that the surface 11 of the first wafer 1 that is embodied in pyramid-like fashion is completely impressed into that surface of the photoresist 2 which is remote from the second semiconductor wafer 3. In other words, the negative form of the patterned surface 11 of the first wafer 1 is applied on that surface of the photoresist 2 which is remote from the second semiconductor wafer 3. After impressing the structure, the wafer 1 is removed from the photoresist 2 and a surface 21 embodied in pyramid-like fashion with pyramid-like elevations 211 remains. The surface 21 is therefore the negative form of the surface 11 and thus has the same geometrical features of a pyramid-like elevation with respect to width b and depth t as the surface 11.

The patterned surface 11 of the first wafer 1 therefore serves as a template for the pyramid-like structure 21 impressed into the surface of the photoresist 2.

Advantageously, the wafer 1 can be reused many times for patterning further photoresist layers, which not only leads to a considerable time saving in the fabrication process but also has a cost-saving effect on the entire production process.

FIG. 3 shows the application of a patterning method 6 to the pyramidally patterned outer area 21 of the photoresist 2. In the present case, the patterning method 6 is a dry-chemical etching process 61. By way of example, this can involve reactive ion etching (RIE) or ion beam etching (IBE). The dry-chemical etching process 61 is preferably a plasma etching process.

At places of the second semiconductor wafer 3 at which the photoresist 2 is very thin, the photoresist 2 is etched away rapidly. After just a short etching duration, the photoresist 2 has been removed at the thinly coated places, while residues of the photoresist 2 are still present at other places, coated more thickly with photoresist 2, of the second semiconductor wafer 3. At places, however, at which the photoresist 2 is thicker, a very small etching depth into the second semiconductor wafer 3 is achieved. That is to say that after a specific etching duration, etching into the second semiconductor wafer 3 already takes place at the places thinly coated with the photoresist 2, while the photoresist 2 is still being etched away at least in places at the more thickly coated places.

If a desired and predeterminable structure of an outer area 31 of the second semiconductor wafer 3 has been achieved, then the etching process can be stopped. Furthermore, the etching process can be set by a predeterminable selectivity with respect to the materials of the photoresist 2 and of the second semiconductor wafer 3. In the present case, a selectivity of 1:1 was chosen with regard to the etching method. That is to say that the etching method, for example, with regard to its etching rate, has the same etching rate both during the etching of the photoresist 2 and during the etching of the semiconductor wafer 3. This can lead to an identical mapping of the pyramid-like elevations 211 of the photoresist layer 21 patterned in pyramid-like fashion onto the surface of the second semiconductor wafer 3.

FIG. 3 shows the semiconductor wafer 3 with the outer area 31 patterned in pyramid-like fashion. In a side view of the semiconductor wafer 3, each pyramid-like elevation 311 has two side areas 301, a base area 302 and a top area 303. Since a selectivity of 1:1 in the etching process is chosen, it is possible to form the pyramidally patterned outer area 31 of the second semiconductor wafer 3 with the same geometrical features with regard to etching depths (t₁ and t₂), and widths (b₁ and b₂) as the surface 11 of the first semiconductor wafer 1 that is patterned in pyramid-like fashion.

Pyramidal structures 311 result whose width b₁ and b₂ respectively relative to the etching depth t₁ and t₂ respectively, in the present exemplary embodiment, satisfy the following relationship: t/b=2.

The outer area 31 of the second semiconductor wafer 3 that is patterned in pyramid-like fashion is therefore the negative form of the patterned surface 11 of the first semiconductor wafer 1.

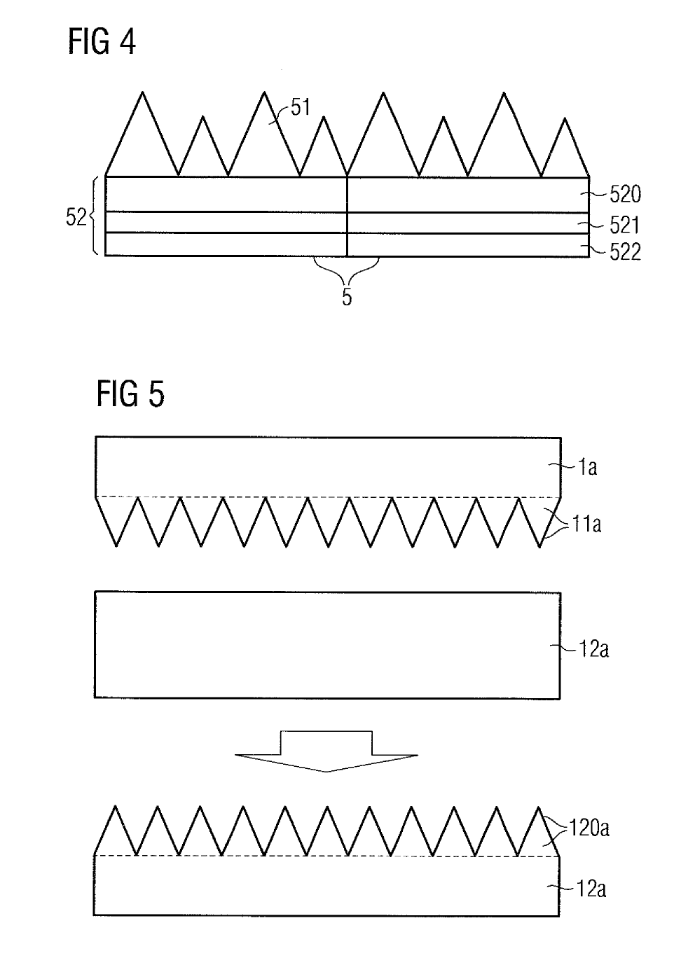

FIG. 4 shows, in a schematic sectional illustration, an assemblage composed of a plurality of semiconductor chips 5. Each semiconductor chip 5 has a radiation exit area 51 patterned in pyramid-like fashion, the radiation exit area, in this exemplary embodiment, being formed like the patterned outer area 31 from FIG. 3 with regard to its geometrical features.

Furthermore, the semiconductor chip 5 has a semiconductor body 52 for generating electromagnetic radiation. The semiconductor body 52 is based on phosphide- or arsenide-based compound semiconductor materials.

The semiconductor body 52 is formed with a first semiconductor layer or semiconductor layer sequences 522 and a second semiconductor layer or semiconductor layer sequence 520, wherein an active zone 521 for generating electromagnetic radiation is arranged between the two semiconductor layers 520 and 522. The semiconductor layers or semiconductor layer sequences 520 and 522 can serve as contact layers for the semiconductor chip 5.

The electromagnetic radiation generated by the semiconductor body 52 is coupled out from the semiconductor chip 5 via the radiation exit area 51 embodied in pyramid-like fashion. It can be shown that such a radiation exit area 51 shaped in pyramid-like fashion increases the coupling-out efficiency by 5 to 20% in comparison, for example, with a coupling-out layer shaped in trapezium-like fashion.

Furthermore, FIG. 5 shows individual method steps for patterning an intermediate carrier 12a. The intermediate carrier 12a then replaces the wafer 1 as a template in the patterning method. That is to say that the methods described in conjunction with FIGS. 1 to 4 can also be performed with the intermediate carrier 12a as wafer 1 instead of with a wafer 1 configured as a semiconductor wafer 1.

For this purpose, the surface 11a of a semiconductor wafer 1a that is patterned in pyramid-like fashion is impressed into that surface of the intermediate carrier 12a which faces the semiconductor wafer 1a, and the pyramidal surface 120a is thus produced.

This advantageously affords the possibility of replacing a usually cost-intensive semiconductor wafer by the normally more cost-effective intermediate carrier 12a, which can advantageously also be used for a multiplicity of further patterning methods. Therefore, considerably fewer cost-intensive semiconductor wafers are required for producing a multiplicity of patterned semiconductor surfaces, for example, which leads to a significant cost saving.

The invention is not restricted by the description on the basis of the exemplary embodiment. Rather, the invention encompasses any novel feature and also the combination of features, which, in particular, includes any combination of features in the patent claims, even if this feature, or this combination, is not explicitly specified in the patent claims or the exemplary embodiment.

1. A method for patterning a semiconductor surface, the method comprising:
providing a first wafer that has a patterned surface;
providing a second semiconductor wafer;
applying a photoresist to an outer area of the second semiconductor wafer;
patterning a surface of the photoresist that is remote from the second semiconductor wafer by impressing the patterned surface of the first wafer into the photoresist;
applying a patterning method to the surface of the photoresist, wherein a structure applied on the photoresist is transferred at least in places to the outer area of the second semiconductor wafer.

2. The method according to claim 1, wherein the first wafer comprises a semiconductor wafer.

3. The method according to claim 1, wherein the first wafer comprises an intermediate carrier formed from a plastics material.

4. The method according to claim 1, wherein the first wafer has a maximum diameter that deviates by at most 20% from a maximum diameter of the second semiconductor wafer.

5. The method according to claim 1, wherein the first wafer comprises at least one layer that consists essentially of a nitride-based compound semiconductor material.

6. The method according to claim 1, wherein the second semiconductor wafer comprises at least one layer which consists essentially of a phosphide-based compound semiconductor material.

7. The method according to claim 1, wherein the second semiconductor wafer comprises at least one layer that consists essentially of an arsenide-based compound semiconductor material.

8. The method according to claim 1, wherein the patterning method comprises a dry-chemical etching process.

9. The method according to claim 1, wherein the patterning method comprises a wet-chemical etching process.

10. The method according to claim 1, wherein the structure transferred to the outer area of the second semiconductor wafer comprises a plurality of pyramid-like structures.

11. The method according to claim 10, wherein a ratio t/b of etching depth t to width b for the pyramid-like structures follows 0.1<t/b<10.

12. The method according to claim 11, wherein the etching depth t in the second semiconductor wafer is 50 to 200 nm.

13. A semiconductor chip, comprising:
a semiconductor body, based on phosphide- or arsenide-based compound semiconductor materials; and
a radiation exit area, through which the electromagnetic radiation generated in the semiconductor body is coupled out from the semiconductor chip, wherein the radiation exit area is patterned in pyramidal fashion.

14. The semiconductor chip according to claim 13, wherein the semiconductor chip is produced by a method comprising:
applying a photoresist to an outer area of a second semiconductor wafer;
patterning a surface of the photoresist that is remote from the second semiconductor wafer by impressing a patterned surface of a first wafer into the photoresist; and
applying a patterning method to the patterned surface of the photoresist, wherein the patterned surface of the photoresist is transferred at least in places to the outer area of the second semiconductor wafer.

15. A method for patterning a semiconductor surface, the method comprising:
providing a first wafer that has a patterned surface, the first wafer comprising at least one layer that consists essentially of a nitride-based compound semiconductor material;
applying a photoresist to an outer area of a second wafer, the second wafer comprising a semiconductor wafer;
patterning a surface of the photoresist that is remote from the second wafer by impressing the patterned surface of the first wafer into the photoresist; and
applying a patterning method to the patterned surface of the photoresist, wherein the patterned surface of the photoresist is transferred at least in places to the outer area of the second wafer,the structure transferred to the outer area of the second semiconductor wafer being embodied in pyramid-like fashion.

16. The method according to claim 15, wherein the second wafer comprises at least one layer that consists essentially of a phosphide-based compound semiconductor material.

17. The method according to claim 15, wherein the second wafer comprises at least one layer that consists essentially of an arsenide-based compound semiconductor material.
